(19) United States
(12) Patent Application Publication
(10) Pub. No.: US 2005/0212129 A1
(43) Pub. Date: Sep. 29, 2005

(54) Semiconductor package with build-up structure and method for fabricating the same

(75) Inventors: Chien-Ping Huang, Hsinchu Hsein (TW); Cheng-Hsu Hsiao, Taichung Hsien (TW); Chih-Ming Huang, Hsinchu Hsein (TW)

Correspondence Address: EDWARDS & ANGELL, LLP, P.O. BOX 55874, BOSTON, MA, 02205, US

(73) Assignee: Siliconware Precision Industries Co., Ltd., Taichung Hsien (TW)

(21) Appl. No.: 10/974,293

(22) Filed: Oct. 26, 2004

(30) Foreign Application Priority Data
Mar. 25, 2004 (TW) 093108068

(51) Int. Cl. H01L 21/44; H01L 23/52

(52) U.S. Cl. 257/737; 438/613; 257/676; 438/123

(57) ABSTRACT

A semiconductor package with a build-up structure is provided, which includes a rigid base, a rigid frame having a through hole and fixed onto the rigid base, at least one chip received in the through hole of the rigid frame, a medium filled in a gap between the chip and the rigid frame, a build-up structure formed on the chip and the rigid frame and electrically connected to the chip, and a plurality of conductive elements bonded to the build-up structure to electrically connect the chip to external devices. The use of the rigid base and rigid frame can avoid structural warpage, cracking, delamination and a popcorn effect of the semiconductor package. A method for fabricating the semiconductor package is also provided.

### FIELD OF THE INVENTION

The present invention relates to semiconductor packages and methods for fabricating the same, and more particularly, to a semiconductor package having a build-up structure formed on an active surface of a chip such that the distribution of external contacts where solder balls are bonded is fanned out to the area outside the active surface of the chip, and a method for fabricating the semiconductor package.

### BACKGROUND OF THE INVENTION

Due to the requirements for compact and light-weight electronic products, semiconductor packages serving as primary components for the electronic products are being miniaturized in size. Chip Scale Package (CSP) is one kind of miniaturized semiconductor packages developed in the industry, which is characterized in that the size of such package is merely equal to or about 1.2 times larger than the size of a chip incorporated therein.

In addition to the requirement for miniaturization in size, high integration and a large number of input/output contacts for electrical connection with external devices such as circuit boards are also necessary for the semiconductor packages so as to provide high performance and high processing speed for the electronic products. Generally, the number of bond pads provided on an active surface of a chip is maximized to increase the number of input/output contacts. However, the number of bond pads on the active surface is restricted by the limited area of the active surface and a pitch between adjacent bond pads. In order to dispose more input/output contacts on the limited area of the chip, a wafer-level semiconductor package such as wafer-level CSP has been developed.

Redistribution Layer (RDL) Technology is employed in the wafer-level semiconductor package, by which a dielectric layer is formed on the active surface of the chip, and openings are provided in the dielectric layer to expose the bond pads on the active surface of the chip. Then a plurality of conductive traces are formed on the dielectric layer, wherein one end of each conductive trace is electrically connected to one of the bond pads on the chip, and the other end of each conductive trace is formed as a contact. Subsequently a solder mask layer is disposed over the dielectric layer and covers the conductive traces and the bond pads. Finally a plurality of openings are formed in the solder mask layer to expose the contacts of the conductive traces such that solder balls can be bonded to the exposed contacts. Although the above build-up structure formed by the RDL technology may effectively increase the number of input/output contacts of the chip for electrical connection with external devices, the limited area of the active surface of the chip still sets a restriction on the total number of input/output contacts.

In order to further increase the number of input/output contacts of the chip for electrical connection with external devices, an approach has been proposed in which the distribution of input/output contacts is fanned out to the area outside the active surface of the chip. Referring to FIG. 6, U.S. Pat. No. 6,271,469 has disclosed a semiconductor package 6 in which an encapsulated chip is formed with a build-up structure having an expanded area larger than that of the chip. This semiconductor package 6 includes a chip 60 encapsulated in an encapsulant 62 formed by a molding process. An active surface 602 of the chip 60 is exposed from a surface 622 of the encapsulant 62. A build-up structure 64, comprising a dielectric layer 642, conductive traces 644 and a solder mask layer 646, is formed over the active surface 602 of the chip 60 and the surface 622 of the encapsulant 62. The build-up structure 64 is electrically connected to bond pads 604 of the chip 60 via the conductive traces 644. When solder balls 66 are mounted on the build-up structure 64 and electrically connected to the conductive traces 644, the chip 60 can be electrically connected to external devices via the solder balls 66.

The above semiconductor package 6 can provide a larger disposing area for input/output contacts and thus increase the number of input/output contacts. However, since the encapsulant 62 is not formed on a substrate with relatively greater rigidity and a central portion of the encapsulant 62 mounted with the chip 60 is thinner than a peripheral portion thereof, warpage may easily occur and cracking is produced at a position 624 due to concentrated stress during a temperature cycle in subsequent fabrication processes. Moreover, as the chip 60 is substantially encapsulated by the encapsulant 62, delamination may easily occur between the chip 60 and encapsulant 62 due to mismatch in coefficient of thermal expansion (CTE) between those two materials, thereby degrading the quality of fabricated products.

In light of the drawbacks of the semiconductor package disclosed in U.S. Pat. No. 6,271,469, another type of semiconductor package with a glass substrate for carrying a chip has been proposed in U.S. Pat. No. 6,498,387. Referring to FIG. 7, in this semiconductor package 7, a chip 70 is attached to a glass substrate 71 and encapsulated by an epoxy resin layer 72, wherein openings are formed in the epoxy resin layer 72 to expose bond pads 702 of the chip 70. A plurality of conductive traces 73 are then formed on the epoxy resin layer 72 and electrically connected to the bond pads 702. A solder mask layer 74 is applied over the epoxy resin layer 72 to cover the conductive traces 73. Then a plurality of openings are formed in the solder mask layer 74 to expose part of the conductive traces 73 for allowing solder balls 75 to be mounted on the exposed part of conductive traces 73.

In U.S. Pat. No. 6,498,387, the glass substrate 71 is used as a carrier for the chip 70. The rigidity of the glass substrate 71 can solve the problems of warpage and cracking of the encapsulant encountered in U.S. Pat. No. 6,271,469. Moreover, since the glass substrate 71 and the chip 70 have similar CTEs, the foregoing problem of delamination caused by mismatch in CTE can be avoided. However, in U.S. Pat. No. 6,498,387, the chip 70 is entirely encapsulated by the epoxy resin layer 72, which may cause cracking of the chip 70 due to thermal stress during the temperature cycle in subsequent fabrication processes by virtue of the CTE mismatch between the chip 70 and the epoxy resin layer 72. Furthermore, side walls 720 of the epoxy resin layer 72 are exposed to the atmosphere, such that external moisture can enter the epoxy resin layer 72 and is accumulated on an active surface of the chip 70 due to the high moisture absorptivity of the epoxy resin layer 72. This situation would lead to a popcorn effect and further decrease the reliability of fabricated products.

Therefore, the problem to be solved here is to provide a semiconductor package, which can eliminate the drawbacks raised in U.S. Pat. Nos. 6,271,469 and 6,498,387.

### SUMMARY OF THE INVENTION

An objective of the present invention is to provide a semiconductor package with a build-up structure, which can avoid warpage, cracking and delamination and thus improve the reliability thereof.

Another objective of the present invention is to provide a method for fabricating a semiconductor package with a build-up structure, without having to form an encapsulant by an injection mold.

Still another objective of the present invention is to provide a semiconductor package with a build-up structure, which has a better anti-popcorn performance and thus improves the reliability thereof.

A further objective of the present invention is to provide a semiconductor package with a build-up structure, which provides satisfactory protection for a chip incorporated therein and thus improves the reliability thereof.

In accordance with the above and other objectives, the present invention proposes a semiconductor package with a build-up structure, including: a rigid base; a rigid frame fixed onto the rigid base and having at least one through hole; at least one chip received in the through hole of the rigid frame and mounted on the rigid base via an inactive surface of the chip, wherein a gap is formed between the chip and the rigid frame, and the chip is similar in thickness to the rigid frame; a medium filled in the gap; a build-up structure formed on the chip and the rigid frame and electrically connected to the chip; and a plurality of conductive elements electrically connected to the build-up structure.

The build-up structure is made in accordance with that disclosed in U.S. Patent Nos. 6,271,469 and 6,498,387, comprising: at least one dielectric layer, a plurality of conductive traces formed on the dielectric layer and electrically connected to bond pads on an active surface of the chip, a solder mask layer applied over the dielectric layer and the conductive traces and having a plurality of openings for allowing the conductive elements to be electrically connected to the conductive traces.

The present invention also proposes a method for fabricating a semiconductor package with a build-up structure, including the steps of: preparing a rigid base such as a rigid plate with an appropriate thickness, and preparing a module board comprising a plurality of rigid frames arranged as an array, each of the rigid frames having at least one through hole; fixing the module board onto the rigid base; mounting at least one chip on the rigid base and in each of the through holes of the rigid frames, wherein a predetermined gap is formed between each of the chip and the corresponding rigid frame; filling a medium in the gaps such that each of the chips and the corresponding rigid frame are separated by the medium; forming a build-up structure on active surfaces of the chips and the module board, the build-up structure being electrically connected to the chips; electrically connecting a plurality of conductive elements to the build-up structure, for allowing the chips to be electrically connected to external devices via the conductive elements; and performing a singulation process to form individual semiconductor packages with the build-up structure.

In another preferred embodiment of the present invention, the chips can be firstly mounted at predetermined positions on the rigid base. Then, the module board is fixed onto the rigid base, allowing each of the chips to be received in a corresponding one of the through holes of the rigid frames.

It should be noted that “rigid frame” and “rigid base” described herein are respectively referred to as a frame and a plate made of chemical engineering materials known in the art, which would not encounter warpage or deformation under a high temperature or during a temperature cycle. The medium is referred to as a material with a thermoelastic effect and low CTE, or a polymer material such as epoxy resin used for encapsulating chips in the art.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package according to a first preferred embodiment of the present invention;

FIGS. 2A to 2F are schematic diagrams showing steps of a method for fabricating the semiconductor package in FIG. 1;

FIGS. 3A to 3B are schematic diagrams showing steps for fabricating the semiconductor package in FIG. 1 prior to forming a build-up structure according to a second preferred embodiment of the present invention;

FIG. 4 is a cross-sectional view of a semiconductor package according to a third preferred embodiment of the present invention;

FIG. 5 is a top view of a rigid frame according to another preferred embodiment used in the semiconductor package;

FIG. 6 (PRIOR ART) is a cross-sectional view of a semiconductor package disclosed in U.S. Pat. No. 6,271,469; and

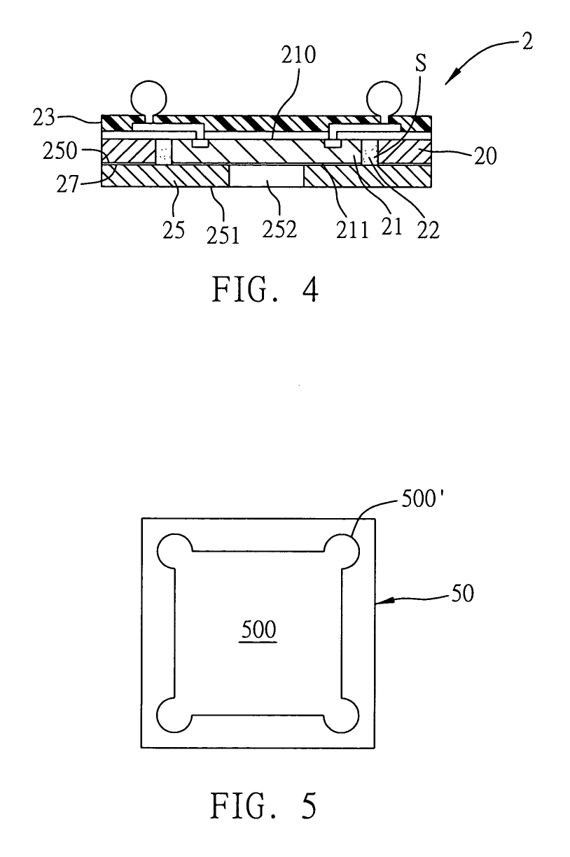

FIG. 7 (PRIOR ART) is a cross-sectional view of a semiconductor package disclosed in U.S. Pat. No. 6,498,387.

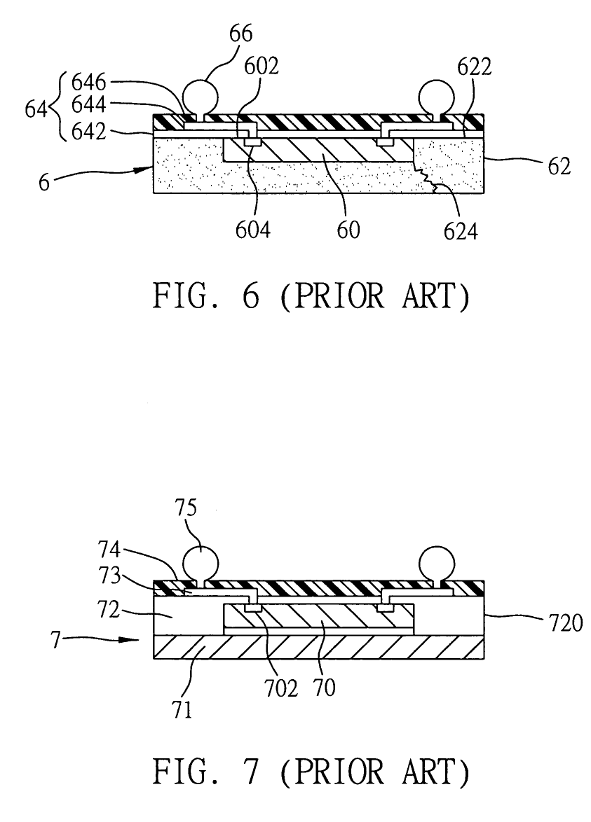

### DETAILED DESCRIPTION OF THE PREFERRED EMBODIMENTS

### First Preferred Embodiment

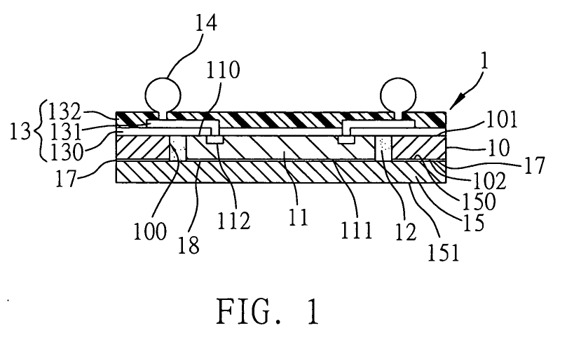

Referring to FIG. 1, a semiconductor package 1 with a build-up structure according to the present invention comprises: a rigid base 15; a rigid frame 10 with a through hole 100; a chip 11 received in the through hole 100 of the rigid frame 10; a medium such as a resin material 12 filled in a gap between the rigid frame 10 and the chip 11; a build-up structure 13 formed over the rigid frame 10 and the chip 11; and a plurality of solder balls 14 (equivalent to the foregoing conductive elements) mounted on the build-up structure 13.

The rigid base 15 and the rigid frame 10 can be made of a glass material, metal material (such as copper and the like), or thermosetting material (such as polyimide resin, bismaleimide triazine resin, FR-4 resin, and the like). The rigid base 15 and the rigid frame 10 do not encounter warpage and deformation under a high temperature or during a temperature cycle in fabrication processes and thus serve as a primary structured body of the semiconductor package 1. As a result, the fabricated semiconductor package is free of a concern of warpage, and its rigidity can avoid a problem of cracking of a chip-encapsulation encapsulant at positions corresponding to corners of the chip as described above for U.S. Pat. No. 6,271,469.

The rigid base 15 has a first surface 150 and a second surface 151 opposite to the first surface 150. The rigid frame 10 has a first surface 101 and a second surface 102. The through hole 100 penetrates the first surface 101 and the second surface 102 of the rigid frame 10, and is preferably located at a central position of the rigid frame 10. When fixing the rigid frame 10 onto the rigid base 15, at least one of the second surface 102 of the rigid frame 10 and the first surface 150 of the rigid base 15 is applied with an adhesive 17 such that the second surface 102 of the rigid frame 10 can be attached to the first surface 150 of the rigid base 15 via the adhesive 17. Then an appropriate curing process is performed to cure the adhesive 17.

The chip 11 includes an active surface 110 and an inactive surface 111 opposite to the active surface 110, wherein the active surface 110 is provided with electronic components, electronic circuits and a plurality of bond pads 112 thereon. When the chip 11 is received within the through hole 100 of the rigid frame 10, the active surface 110 and is coplanar with the first surface 101 of the rigid frame 10, and the inactive surface 111 is coplanar with the second surface 102 of the rigid frame 10. In other words, the chip 11 is similar in thickness to the rigid frame 10. Moreover, the chip 11 is received in the through hole 100 with a gap being formed between the chip 11 and the rigid frame 10, such that the chip 11 is not in contact with the rigid frame 10. Further, the inactive surface 111 of the chip 11 can be attached to the first surface 150 of the rigid base 15 by an adhesive 18.

The resin material 12 can be a material with low modulus such as polyimide resin, silica gel, epoxy resin, and the like. With the resin material 12 being filled in the gap between the chip 11 and the rigid frame 10, the resin material 12 has certain flexibility and serves as a buffer medium between the chip 11 and the rigid frame 10 so as to effectively release thermal stress exerted on the chip 11 from the rigid frame 10 due to mismatch in CTE between the chip 11 and the rigid frame 10 during the temperature cycle in fabrication processes. Thus cracking and delamination of the chip 11 can be avoided, and the yield and reliability of the semiconductor package 1 according to the present invention can be improved.

The build-up structure 13 comprises a dielectric layer 130 applied over the chip 11 and the rigid frame 10; a plurality of conductive traces 131 formed on the dielectric layer 130 and electrically connected to the bond pads 112 of the chip 11; and a solder mask layer 132 for covering the dielectric layer 130 and the conductive traces 131. The build-up structure 13 and its fabricating method are known in the art and thus not to be further described herein. Further, if necessary, at least one more dielectric layer and more conductive traces (not shown) can be formed on the dielectric layer 130 and the conductive traces 131 in the build-up structure 13.

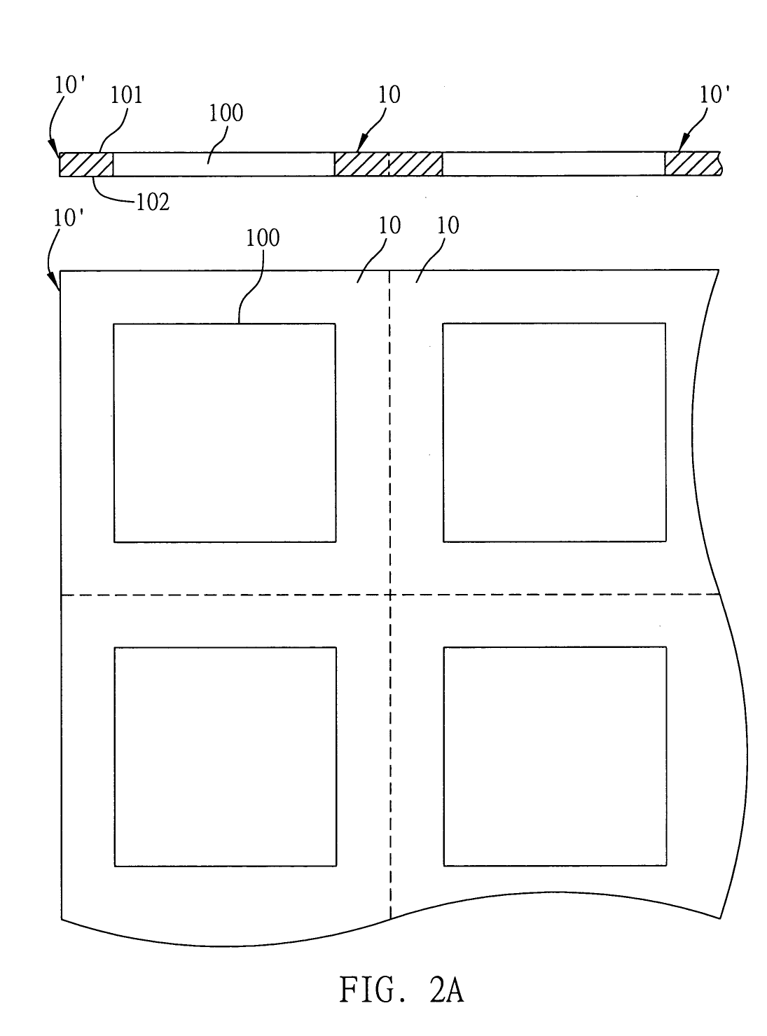

FIGS. 2A to 2F shows the steps of a method for fabricating the semiconductor package described above.

Referring to FIG. 2A, the first step for fabricating the semiconductor package according to the first embodiment of the present invention is to prepare a module board 10′ made of glass, which comprises a plurality of rigid frames 10 each having a rectangular through hole 100 located at a central position thereof. Each of the rigid frames 10 has a first surface 101 and a second surface 102 opposite to the first surface 101.

Referring to FIG. 2B, the module board 10′ is fixed onto a rigid base 15 made of glass. The rigid base 15 has a first surface 150 and a second surface 151 opposite to the first surface 150. During the fixing process, at least one surface of the second surface 102 of the rigid frame 10 and the first surface 150 of the rigid base 15 is applied with an adhesive 17 such as UV curing paste. Then, the second surface 102 of the rigid frame 10 is attached to the first surface 150 of the rigid base 15 via the adhesive 17. The adhesive 17 is cured by irradiation of UV light at an appropriate wavelength for an appropriate period of time so as to fix the module board 10′ onto the rigid base 15.

Referring to FIG. 2C, a chip 11 is mounted in each of the through holes 100 in a manner that an inactive surface 111 of the chip 11 downwardly faces the first surface 150 of the rigid base 15 and an active surface 110 of the chip 11 faces upwardly and is exposed to the atmosphere. Before mounting the chip 11, at least one of the inactive surface 111 of the chip 11 and a corresponding predetermined location on the first surface 150 of the rigid base 15 is applied with an adhesive 18 such as UV curing paste, such that the inactive surface 111 of the chip 11 can be attached to the first surface 150 of the rigid base 15 when the chip 11 is mounted in the corresponding through hole 100. Furthermore, the chip 11 is similar in thickness to the module board 10′, such that when the chip 11 is mounted in the through hole 100 and on the rigid base 15, the active surface 110 thereof is coplanar with the first surface 101 of the corresponding rigid frame 10. Moreover, the cross-sectional area of the through hole 100 is larger than the surface area of the chip 11. Thus, the chip 11 is received in the through hole 100 and not in contact with walls of the through hole 100, with a predetermined gap S being formed between the chip 11 and the walls of the through hole 100. After the chip is placed on the predetermined location of the rigid base 15 and within the through hole 100, the adhesive 18 is cured from bottom by irradiation of UV light at an appropriate wavelength for an appropriate period of time so as to fix the chip 11 onto the rigid base 15.

Referring to FIG. 2D, an appropriate amount of a resin material 12, such as silicon gel, epoxy resin, polyimide resin, and the like, is dispensed into the gap S between each chip 11 and the corresponding rigid frame 10 by a dispenser apparatus 16. Then, the resin material 12 is uniformly filled in each of the gaps S by a capillary effect.

Referring to FIG. 2E, a dielectric layer 130 is disposed on the first surfaces 101 of the rigid frames 10 and the active surfaces 110 of the chips 11, and a plurality of through holes (not designated with a reference numeral) are formed in the dielectric layer 130 at positions corresponding to the bond pads 112 on the active surfaces 110 of the chips 11 by conventional techniques including, but are not limited to, a photolithographic technique and a laser drilling technique. Then, a plurality of patterned conductive traces 131 are formed on the dielectric layer 130 by a conventional technique such as, but not limited to, the photolithographic technique. One end of each conductive trace 131 is electrically connected to one of the bond pads 112 of the corresponding chip 11 via the through hole of the dielectric layer 130, and the other end of each conductive trace 131 is formed as a contact terminal (not designated with a reference numeral) that may be located outside from the periphery of the chip 11. Next, a solder mask layer 132 is applied over the conductive traces 131 and the dielectric layer 130, and a plurality of openings (not designated with a reference numeral) are formed in the solder mask layer 132 by any conventional technique to expose the contact terminals of the conductive traces 131, such that solder balls 14 can be mounted on the exposed contact terminals of the conductive traces 131 respectively. As a result, the solder balls 14 are electrically connected to the build-up structure 13 comprising the dielectric layer 13, the conductive traces 131 and the solder mask layer 132. The material of the solder balls 14 and the method of mounting the solder balls 14 to the build-up structure 13 are known in the art and thus not to be further described herein.

Finally, referring to FIG. 2F, a singulation process is performed by any conventional technique to form a plurality of the individual semiconductor packages 1 shown in FIG. 1.

In the semiconductor package 1 according to the present invention, the chip 11 and the rigid frame 10 is separated by the resin material 12 that may effectively release thermal stress generated by the rigid frame 10 during the temperature cycle in fabrication processes. The rigid frame 10 and the rigid base 15 serve as the primary structured body of the semiconductor package 1 without having to use a molding compound or encapsulant for encapsulating the chip, such that the fabrication processes are simplified and the problems of warpage of the encapsulant and cracking and delamination of the chip in the prior art can be avoided. Moreover, the chip 11 and the resin material 12 are fully enclosed by the rigid frame 10, the rigid base 15 and the build-up structure 13 and are isolated from the external atmosphere. This can prevent the resin material 12 from absorbing external moisture and avoid a popcorn effect during the temperature cycle, thereby assuring the reliability of the semiconductor package 1.

For further thinning the semiconductor package 1 proposed in the present invention, after the step shown in FIG. 2D, a grinding process can be performed on the second surface 151 of the rigid base 15 by a conventional technique such as but not limited to mechanical grinding, so as to reduce the thickness of the rigid base 15. The grinding process is known in the art and thus not to be further described and illustrated by drawings herein.

### Second Preferred Embodiment

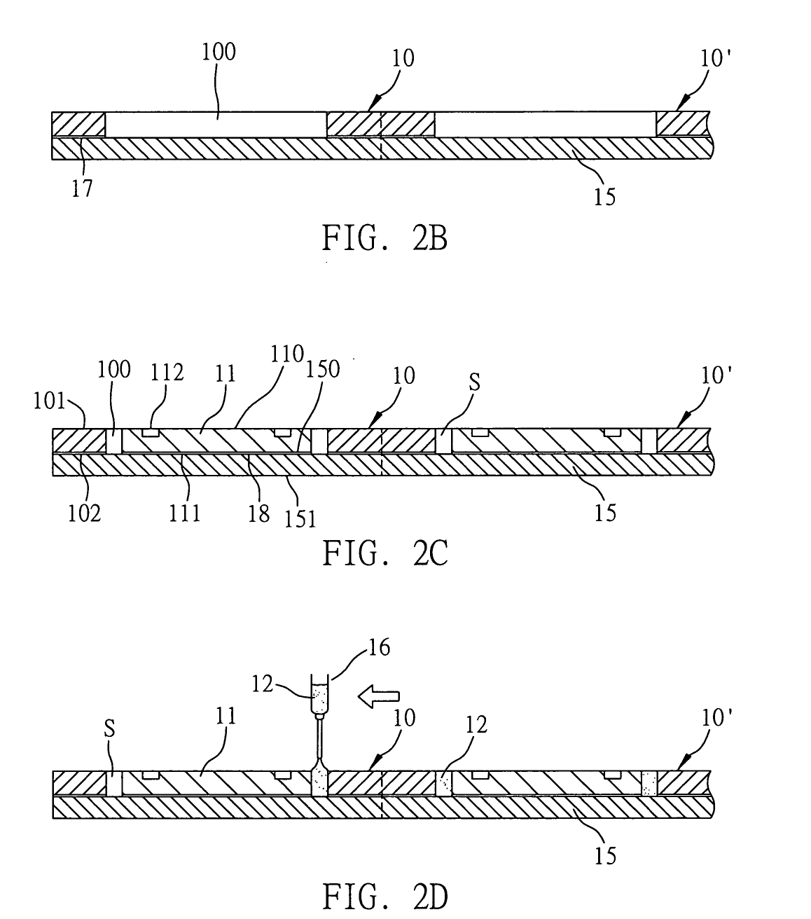

The method for fabricating a semiconductor package according to the second embodiment of the present invention is similar to that of the foregoing first embodiment. Therefore, only the fabrication steps in the second embodiment different from those in the first embodiment are described below with reference to FIGS. 3A to 3B. In FIGS. 3A to 3B, the same or similar components with those in FIGS. 2A to 2B are indicated by the same reference numerals.

Referring to FIG. 3A, a module board 10′ comprising a plurality of rigid frames 10 arranged as an array is provided. Each of the rigid frames 10 has a rectangular through hole 100, a first surface 101, and a second surface 102 opposite to the first surface 101. Also, a rigid base 15 having a first surface 150 and a second surface 151 is provided. Moreover, a plurality of chips 11 are fixed at predetermined locations on the rigid base 15 by the following steps: applying an adhesive 18 to at least one of the first surface 150 of the rigid base 15 and an inactive surface 111 of each chip 11, then attaching the inactive surface 111 of the chip 11 to the first surface 150 of the rigid base 15, and finally curing the adhesive 18 by an appropriate curing process.

Referring to FIG. 3B, the module board 10′ is fixed onto the rigid base 15, such that each of the chips 11 is received in one of the through holes 100 of the rigid frames 10, and a gap S is formed between each chip 11 and the corresponding rigid frame 10. The method for fixing the module board 10′ onto the rigid base 15 can be the same as above described, that is, applying an adhesive 17 to at least one of the surfaces for attachment, and then curing the adhesive 17 by an appropriate curing process after attaching the surfaces together.

In a preferred embodiment, the process for curing the adhesive 18 for fixing the chips 11 and the rigid base 15 is substantially identical to the process for curing the adhesive 17 for fixing the module board 10′ and the rigid base 15. Therefore, alternatively, after all the chips 11 and the module board 10′ are placed on the rigid base 15, the adhesive 18 between the chips 11 and the rigid base 15 as well as the adhesive 17 between the rigid base 15 and the module board 10′ can be cured at the same time, so as to reduce fabrication procedure complexity and processing time.

The subsequent steps of fabricating the semiconductor package include: dispensing a resin material 12 into the gaps S between the chips 11 and the rigid frames 10, forming a build-up structure 13 on active surfaces 110 of the chips 11, mounting solder balls, and performing a singulation process. These procedures and the products thereby are the same as those in the first embodiment, and thus are not to be further described and illustrated by drawings herein.

### Third Preferred Embodiment

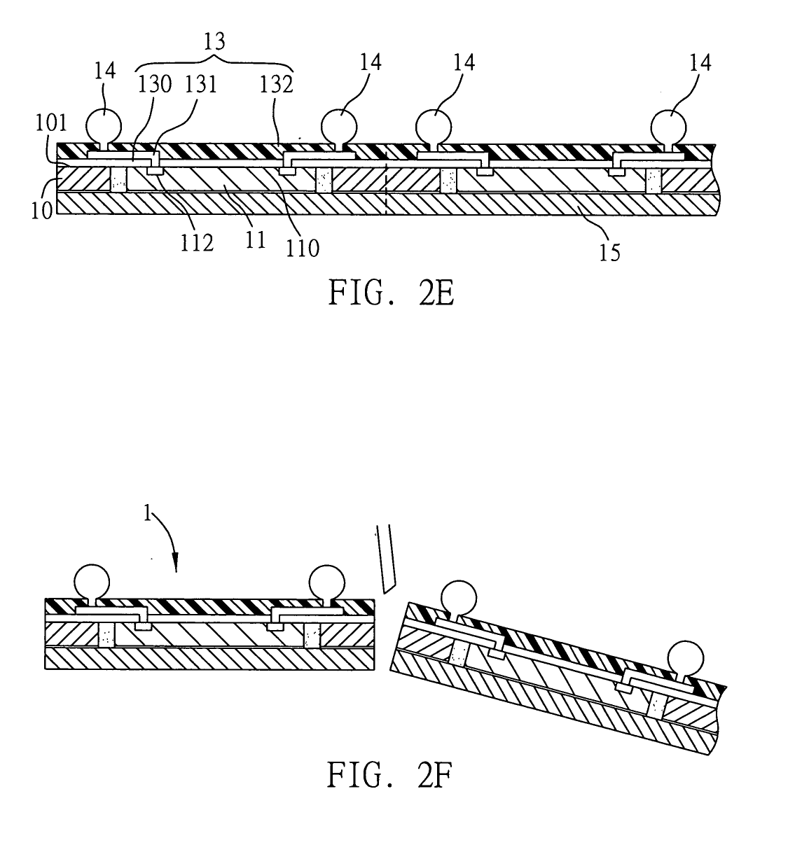

The structure of a semiconductor package 2 disclosed in the third embodiment of the present invention is similar to that in the first embodiment, with a difference in that a rigid base 25 in the semiconductor package 2 is formed with a through hole 252 at a central position of a predetermined location thereof for mounting a chip 21 thereon as shown in FIG. 4.

The steps of fabricating the semiconductor package 2 include: preparing the rigid base 25 having a first surface 250, a second surface 251 and at least one through hole 252, wherein the through hole 252 is formed at a central position of a predetermined location on the rigid base 25 for mounting a chip; then, fixing a rigid frame 20 onto the rigid base 25 via an adhesive 27 as similarly described in the first embodiment; placing a chip 21 on the rigid base 25 and in the rigid frame 20, wherein a gap S is formed between the chip 21 and the rigid frame 20, and an inactive surface 211 of the chip 21 downwardly faces the through hole 252 of the rigid base 25; and finally drawing air out from the through hole 252 so as to fix the chip 21 onto the rigid base 25 by vacuum.

The subsequent steps of fabrication for the semiconductor package 2 include: dispensing a resin material 22 into the gap S between the chip 21 and the rigid frame 20, forming a build-up structure 23 on an active surface 210 of the chip 21, mounting solder balls, and performing a singulation process. These procedures and the products thereby are the same as those in the first embodiment, and thus are not to be further described and illustrated by drawings herein.

### Fourth Preferred Embodiment

The structure of a semiconductor package disclosed in the fourth embodiment of the present invention is similar to that in the first embodiment, with a difference in that the semiconductor package in the fourth embodiment has improved heat dissipation efficiency. In this embodiment, a material with higher coefficient of heat dissipation, such as copper, is used for making the rigid base 15, and the adhesive 18 for attaching the rigid base 15 and the chip 11 is a thermally conductive paste. Therefore, heat generated by the chip 11 can be dissipated to the atmosphere via the adhesive 18 and the rigid base 15.

### Fifth Preferred Embodiment

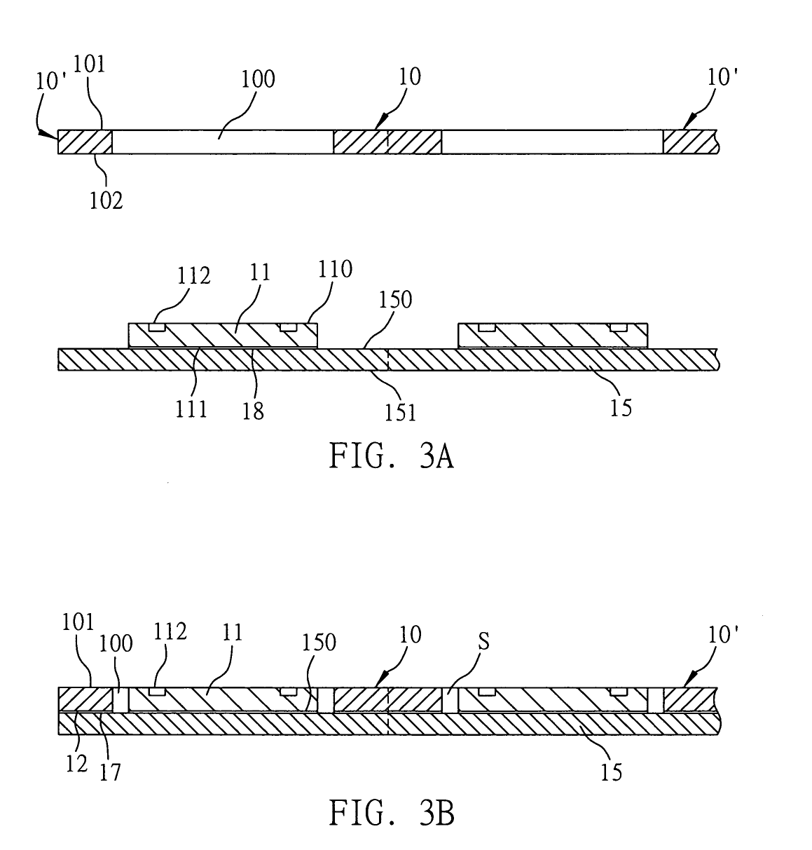

FIG. 5 is a top view of a rigid frame according to another embodiment of the present invention. This rigid frame 50 in the fifth embodiment is similar to that in each of the foregoing embodiments. Differently, in order to further prevent the rigid frame 50 from cracking at corners 500′ of a through hole 500 thereof caused by concentrated stress, the corners 500′ of the through hole 500 are rounded or chamfered to effectively release the stress concentration effect, so as to avoid cracking of the rigid frame 50.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor package with a build-up structure, comprising:
a rigid base;
a rigid frame having at least one through hole and fixed onto the rigid base;
at least one chip received in the through hole of the rigid frame and mounted on the rigid base, wherein a gap is formed between the chip and the rigid frame;
a medium filled in the gap between the chip and the rigid frame;
a build-up structure formed on the rigid frame and the chip and electrically connected to the chip; and
a plurality of conductive elements electrically connected to the build-up structure, for allowing the chip to be electrically connected to external devices.

2. The semiconductor package of claim 1, wherein the rigid frame is similar in thickness to the chip.

3. The semiconductor package of claim 1, wherein the through hole is a rectangular hole.

4. The semiconductor package of claim 3, wherein corners of the through hole are rounded or chamfered.

5. The semiconductor package of claim 1, wherein the rigid base is made of a material selected from the group consisting of glass material, metal material, and thermosetting material.

6. The semiconductor package of claim 1, wherein the rigid frame is made of a material selected from the group consisting of glass material, metal material, and thermosetting material.

7. The semiconductor package of claim 1, wherein the medium is made of a material selected from the group consisting of silica gel, epoxy resin, and polyimide resin.

8. The semiconductor package of claim 1, wherein the conductive elements are solder balls.

9. The semiconductor package of claim 1, wherein the rigid base has at least one through hole formed at a position corresponding to the chip.

10. A method for fabricating a semiconductor package with a build-up structure, comprising the steps of:
preparing a module board comprising a plurality of rigid frames arranged as an array, each of the rigid frames having at least one through hole;
fixing the module board onto a rigid base;
mounting at least one chip in each of the through holes of the rigid frames and on the rigid base, wherein a predetermined gap is formed between each of the chips and the corresponding one of the rigid frames of the module board;
filling a medium into the gaps such that each of the chips and the corresponding rigid frame are separated by the medium;
forming a build-up structure on the module board and the chips, the build-up structure being electrically connected to the chips, and electrically connecting a plurality of conductive elements to the build-up structure; and
performing a singulation process to form individual semiconductor packages with the build-up structure.

11. The method of claim 10, wherein the medium is filled into the gaps between the chips and the rigid frames by a dispensing technique.

12. The method of claim 10, wherein the rigid frame is made of a material selected from the group consisting of glass material, metal material, and thermosetting material.

13. The method of claim 10, wherein the medium is made of a material selected from the group consisting of silica gel, epoxy resin, and polyimide resin.

14. The method of claim 10, wherein the conductive elements are solder balls.

15. The method of claim 10, wherein the rigid base has at least one through hole formed at a position corresponding to each of the chips.

16. The method of claim 15, wherein the at least one chip is fixed onto the rigid base by vacuum via the corresponding through hole of the rigid base after mounting the chip in each of the through holes of the rigid frames.

17. A method for fabricating a semiconductor package with a build-up structure, comprising the steps of:
preparing a rigid base;
preparing a module board comprising a plurality of rigid frames arranged as an array, each of the rigid frames having at least one through hole;
mounting at least one chip on the rigid base at a position corresponding to each of the through holes of the rigid frames;
fixing the module board onto the rigid base such that each of the chips is received in a corresponding one of the through holes of the rigid frames, and a predetermined gap is formed between each of the chips and the corresponding rigid frame;
filling a medium into the gaps such that each of the chips and the corresponding rigid frame are separated by the medium;
forming a build-up structure on the module board and the chips, the build-up structure being electrically connected to the chips, and electrically connecting a plurality of conductive elements to the build-up structure; and
performing a singulation process to form individual semiconductor packages with the build-up structure.

18. The method of claim 17, wherein the medium is filled into the gaps between the chips and the rigid frames by a dispensing technique.

19. The method of claim 17, wherein the rigid frame is made of a material selected from the group consisting of glass material, metal material, and thermosetting material.

20. The method of claim 17, wherein the medium is made of a material selected from the group consisting of silica gel, epoxy resin, and polyimide resin.

21. The method of claim 17, wherein the conductive elements are solder balls.

22. The method of claim 17, wherein the rigid base has at least one through hole formed at a position corresponding to each of the chips.

23. The method of claim 22, wherein the at least one chip is fixed onto the rigid base by vacuum via the corresponding through hole of the rigid base after mounting the chip in each of the through holes of the rigid frames.
